(19) United States
(12) Patent Application Publication
(10) Pub. No.: US 2015/0294873 A1
(43) Pub. Date: Oct. 15, 2015

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Huyong LEE, Seoul (KR); Jae-Jung KIM, Suwon-si (KR); Wandon KIM, Yongin-si (KR); Sangjin HYUN, Suwon-si (KR)

(21) Appl. No.: 14/636,257

(22) Filed: Mar. 3, 2015

(30) Foreign Application Priority Data
Apr. 15, 2014 (KR) 10-2014-0044928

(51) Int. Cl. H01L 21/28; H01L 29/423; H01L 29/49; H01L 21/283

(52) U.S. Cl. CPC H01L 21/28008; H01L 21/283; H01L 29/42372; H01L 29/4966

(57) ABSTRACT

Provided is a method of fabricating a semiconductor device, including forming an interlayered insulating layer having an opening, on a substrate; sequentially forming a first conductive pattern, a barrier pattern, and a second conductive pattern on bottom and side surfaces of the opening; and nitrifying an upper portion of the second conductive pattern to form a metal nitride layer that is spaced apart from the first conductive pattern.

### CROSS-REFERENCE TO RELATED APPLICATION

Korean Patent Application No. 10-2014-0044928, filed on Apr. 15, 2014, in the Korean Intellectual Property Office, and entitled: “Semiconductor Device and Method of Fabricating the Same,” is incorporated by reference herein in its entirety.

### BACKGROUND

1. Field

Example embodiments relate to a semiconductor device, for example, a semiconductor device including a transistor and a method of fabricating the same.

2. Description of the Related Art

Semiconductor devices are increasingly being used in consumer, commercial and other electronic devices. Semiconductor devices may be classified into memory devices for storing data, logic devices for processing data, and hybrid devices including both of memory and logic elements. Increased demand for electronic devices with fast speed and/or low power consumption may require semiconductor devices with improved properties, for example, high reliability, high performance, and/or multiple functions, and complexity and/or integration density of semiconductor devices may be increased.

### SUMMARY

Embodiments may be realized by providing a method of fabricating a semiconductor device, the method including forming, on a substrate, an interlayered insulating layer having an opening; sequentially forming a first conductive pattern, a barrier pattern, and a second conductive pattern on bottom and side surfaces of the opening; and nitrifying an upper portion of the second conductive pattern to form a metal nitride layer spaced apart from the first conductive pattern.

The metal nitride layer may contain a different metallic element from one contained in the first conductive pattern.

Forming the first conductive pattern, the barrier pattern, and the second conductive pattern may include conformally forming a first conductive layer on a top surface of the interlayered insulating layer and on the bottom and side surfaces of the opening; conformally forming a barrier layer on the first conductive layer; and forming a second conductive layer on the barrier layer to fill the opening.

Forming the first conductive pattern, the barrier pattern, and the second conductive pattern may further include planarizing the first conductive layer, the barrier layer, and the second conductive layer to expose the interlayered insulating layer.

Nitrifying the upper portion of the second conductive pattern may include nitrifying an upper portion of the first conductive pattern to form a work-function metal nitride layer, and the work-function metal nitride layer may contain a different material from the metal nitride layer.

The work-function metal nitride layer may be spaced apart from the metal nitride layer.

The method may further include forming a gate insulating layer between the first conductive pattern and the opening.

The method may further include forming an oxide layer on the metal nitride layer. The first conductive pattern may have a work function ranging from 4.1 eV to 5.1 eV, after the oxide layer is formed.

Nitrifying the upper portion of the second conductive pattern may include nitrifying an upper portion of the interlayered insulating layer to form an insulating nitride layer.

Embodiments may be realized by providing a semiconductor device, including a substrate; an interlayered insulating layer on the substrate and having an opening; and a gate electrode in the opening, the gate electrode including a first conductive pattern on bottom and side surfaces of the opening; a second conductive pattern on the first conductive pattern; a metal nitride layer spaced apart from the first conductive pattern, on the second conductive pattern; and a barrier layer between the first and second conductive patterns.

The second conductive may contain a different material from the first conductive pattern; and the metal nitride layer may contain a same metal material as the second conductive pattern.

The metal nitride layer may contain a different metallic element from one contained in the first conductive pattern.

The device may further include a work-function metal nitride layer on the first conductive pattern and spaced apart from the metal nitride layer.

The work-function metal nitride layer may be thinner than the metal nitride layer.

The first conductive pattern may have a work function ranging from 4.1 eV to 5.1 eV.

The device may further include a gate insulating layer between the opening and the first conductive pattern.

Embodiments may be realized by providing a method of preventing impurities from infiltrating into a first conductive pattern from a second conductive pattern, the method including forming the first conductive pattern and the second conductive pattern; nitrifying a portion of the second conductive pattern to form a metal nitride layer; and depositing an oxide layer on the metal nitride layer.

The metal nitride layer may be interposed between the oxide layer and a portion of the second conductive pattern that is not nitrified.

Depositing the oxide layer on the metal nitride layer may include depositing the oxide layer on an exposed portion of the first conductive pattern.

The metal nitride layer may prevent a portion of the second conductive pattern that is not nitrified from being oxidized during depositing of the oxide layer.

### BRIEF DESCRIPTION OF THE DRAWINGS

Features will become apparent to those of skill in the art by describing in detail exemplary embodiments with reference to the attached drawings in which:

FIG. 1A illustrates a perspective view of a semiconductor device according to example embodiments;

FIG. 1B illustrates a sectional view taken along line B-B′ of FIG. 1A;

FIGS. 2A through 7A illustrate perspective views of a method of fabricating a semiconductor device according to other example embodiments;

FIGS. 2B through 7B illustrate sectional views taken along lines B-B′ of FIGS. 2A through 7A, respectively;

FIGS. 7C and 7D illustrate sectional views provided to illustrate technical functions of a metal nitride layer in a fabrication process of a semiconductor device;

FIGS. 8A through 10A illustrate perspective views of a method of fabricating a semiconductor device according to still other example embodiments;

FIGS. 8B through 10B illustrate sectional views taken along lines B-B′ of FIGS.

FIGS. 8A through 10A, respectively;

FIG. 11 illustrates a schematic block diagram of an example of electronic systems including a semiconductor device according to example embodiments; and

FIG. 12 illustrates a schematic block diagram of an example of memory systems including a semiconductor device according to the embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on,” “under” versus “directly under”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Unless otherwise defined, all terms (including technical and scientific terms) used herein have the same meaning as commonly understood by one of skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

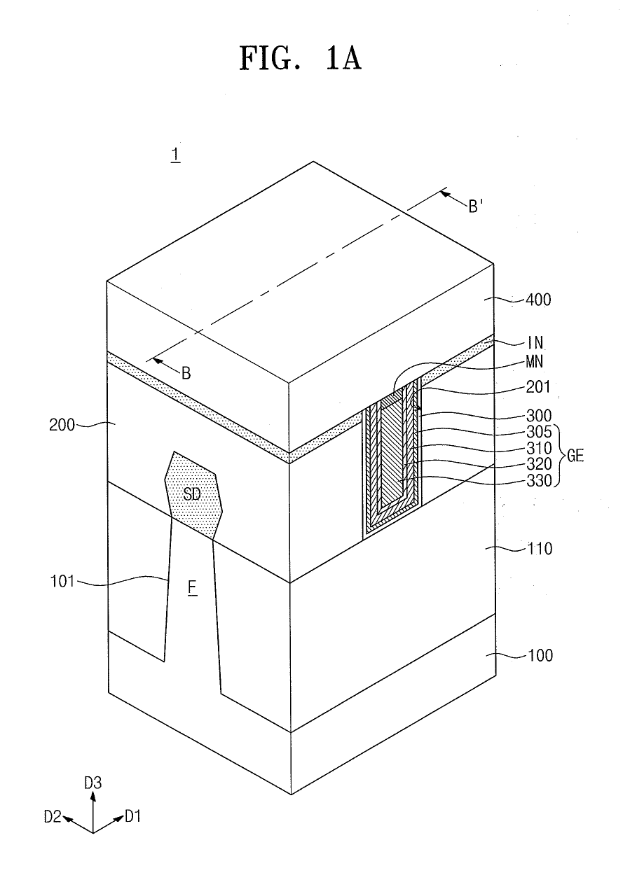

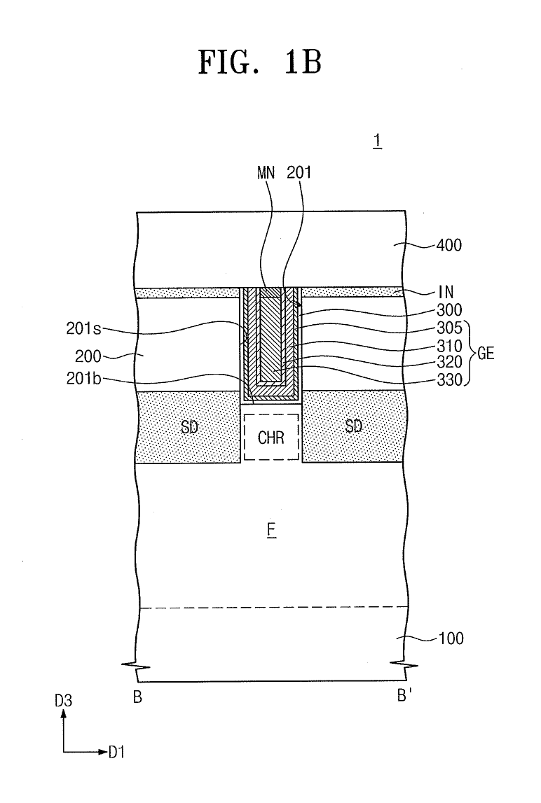

FIG. 1A illustrates a perspective view of a semiconductor device according to example embodiments, and FIG. 1B illustrates a sectional view taken along line B-B′ of FIG. 1A.

Referring to FIGS. 1A and 1B, a semiconductor device 1 may include a substrate 100, an interlayered insulating layer 200, a gate insulating pattern 300, a gate electrode GE, and an oxide layer 400.

The substrate 100 may be a silicon wafer, for example, a bulk silicon wafer or a silicon-on-insulator (SOI) wafer. In other example embodiments, the substrate 100 may be formed of or include at least one of germanium, indium antimonide, lead telluride, indium arsenide, indium phosphide, gallium arsenide, or gallium antimonide.

In an example embodiment, a fin portion F may protrude upward from the substrate 100. The fin portion F may extend along a direction D1. The fin portion F may be formed of a semiconductor material. For example, the fin portion F may be formed of silicon. In example embodiments, the fin portion F may be a portion of the substrate 100. In other words, the fin portion F may be connected to the substrate 100, which is provided in the form of a bulk semiconductor wafer, without any discontinuous interface. The fin portion F may be doped with dopants. The fin portion F may include a channel region CHR. The channel region CHR of the fin portion F may be interposed between source/drain electrodes SD.

A device isolation pattern 110 may be provided on the substrate 100 to enclose the fin portion F. The device isolation pattern 110 may cover at least partially both side surfaces of the fin portion F. The device isolation pattern 110 may be formed using a shallow trench isolation (STI) process.

The interlayered insulating layer 200 may be provided on the substrate 100. The interlayered insulating layer 200 may be formed to have an opening 201 exposing a portion of the substrate 100. The interlayered insulating layer 200 may include at least one of insulating materials, such as silicon oxide, silicon nitride, silicon carbide, or silicon oxynitride. The opening 201 may be formed on the device isolation pattern 110 and the channel region CHR of the fin portion F, and may extend in a direction D2.

The gate insulating pattern 300 may be provided in the opening 201. The gate insulating pattern 300 may be interposed between the channel region CHR of the fin portion F and the gate electrode GE. The gate insulating pattern 300 may be interposed between the gate electrode GE and the interlayered insulating layer 200. The gate insulating pattern 300 may have a “U”-shaped section. For example, the gate insulating pattern 300 may cover bottom and side surfaces 201b and 201s of the opening 201. The gate insulating pattern 300 may include at least one of high-k materials. For example, the gate insulating pattern 300 may include at least one of hafnium-based materials (e.g., HfO₂, HfSiO, HfSiON, HfON, HfAlO, or HfLaO), silicate-based materials (e.g., AlSiO or TaSiO), zirconium-based materials (e.g., ZrO₂ or ZrSiO), lanthanide-based materials (e.g., La₂O₃, Pr₂O₃, or Dy₂O₃), and quaternary oxides (e.g., BST((Ba, Sr)TiO₃) or PZT (Pb(Zr, Ti)O₃)). In other example embodiments, a dielectric layer (not shown) may be additionally interposed between the gate insulating pattern 300 and the opening 201. The dielectric layer may include at least one of silicon oxide, silicon nitride, and silicon carbide.

The gate electrode GE may be provided on the gate insulating pattern 300 in the opening 201. The gate electrode GE may extend in the direction D2. The gate electrode GE may include a first conductive pattern 310, a barrier pattern 320, and a second conductive pattern 330. The gate electrode GE may further include an additional barrier pattern 305. The additional barrier pattern 305 may be disposed between the gate insulating pattern 300 and the first conductive pattern 310. The additional barrier pattern 300 may have a “U”-shaped section and cover the bottom and side surfaces 201b and 201s of the opening 201. The additional barrier pattern 305 may include at least one of metal nitrides, such as TiN, TaN, WN, MN, TiAlN, TaAlN, or HfAlN. In other example embodiments, the additional barrier pattern 305 may be omitted.

The first conductive pattern 310 may be provided on the additional barrier pattern 305. The first conductive pattern 310 may have a “U”-shaped section. For example, the first conductive pattern 310 may be disposed on the bottom and side surfaces 201b and 201s of the opening 201.

The first conductive pattern 310 may be a metal layer for adjusting a work function of the gate electrode GE. The first conductive pattern 310 may be formed of a conductive material having a specific work function and may contribute to adjust a threshold voltage of the channel region CHR. For example, the first conductive pattern 310 may be foamed to have a work function ranging from 4.1 eV to 5.1 eV. The first conductive pattern 310 may include a metal material. For example, the first conductive pattern 310 may be at least one of nitrides or carbides of Ti, Ta, Hf, Mo, or Al. As another example, the first conductive pattern 310 may include at least one of Pt, Ru, IrO, or RuO.

The barrier pattern 320 may be disposed on the first conductive pattern 310. The barrier pattern 320 may have a “U”-shaped section. For example, the barrier pattern 320 may cover the bottom surface 201b and the side surface 201s of the opening 201. The barrier pattern 320 may include at least one of metal nitrides, such as TiN, TaN, WN, HfN, TiAlN, TaAlN, or HfAlN.

The second conductive pattern 330 may be disposed on the barrier pattern 320. The second conductive pattern 330 may be spaced apart from the first conductive pattern 310. The second conductive pattern 330 may have a top surface that is lower than those of the barrier pattern 320 and the first conductive pattern 310. The second conductive pattern 330 may include a different material from the first conductive pattern 310 and the barrier pattern 320. The second conductive pattern 330 may include a metallic material (e.g., tungsten). The second conductive pattern 330 may contain a residue, such as, fluorine, carbon, or oxygen, while the first conductive pattern 310 may not contain such a residue.

A metal nitride layer MN may be provided on the second conductive pattern 330. The metal nitride layer MN may be formed not to cover the barrier pattern 320. The metal nitride layer MN may be spaced apart from the first conductive pattern 310. The barrier pattern 320 may include a portion interposed between an inner side surface of the first conductive pattern 310 and a side surface of the metal nitride layer MN. The metal nitride layer MN may be a portion of the second conductive pattern 330 on which a nitrification process has been performed. The metal nitride layer MN may contain the same metallic element as that contained in the second conductive pattern 330. For example, the second conductive pattern 330 may include tungsten, and the metal nitride layer MN may include tungsten nitride. The metal nitride layer MN may further contain a residue, such as fluorine, carbon, or oxygen. The metal nitride layer MN may have a thickness ranging from about 1 nm to 10 nm. When the thickness of the metal nitride layer MN is greater than 10 nm, the gate electrode GE may suffer from deterioration in electric characteristics (for example, RC delay).

An insulating nitride layer IN may be formed on the interlayered insulating layer 200. The insulating nitride layer IN may not extend on the gate insulating pattern 300 and the first conductive pattern 310. The insulating nitride layer IN may be spaced apart from the metal nitride layer MN. The insulating nitride layer IN may be a portion of the interlayered insulating layer 200, on which a nitrification process has been performed. The insulating nitride layer IN may include at least one of silicon nitride, silicon oxynitride, or silicon carbonitride.

The oxide layer 400 may be provided on the gate electrode GE. The oxide layer 400 may include, for example, silicon oxide. The metal nitride layer MN may be interposed between the second conductive pattern 330 and oxide layer 400. The metal nitride layer MN may prevent the second conductive pattern 330 from being oxidized by the oxide layer 400. The metal nitride layer MN may serve as a barrier layer for preventing oxygen atoms from being diffused from the oxide layer 400 to the second conductive pattern 330.

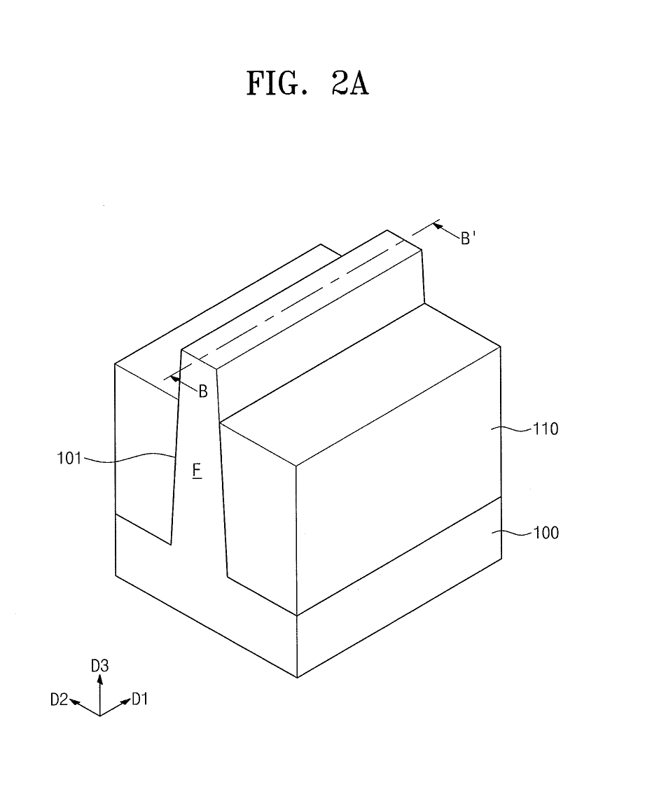

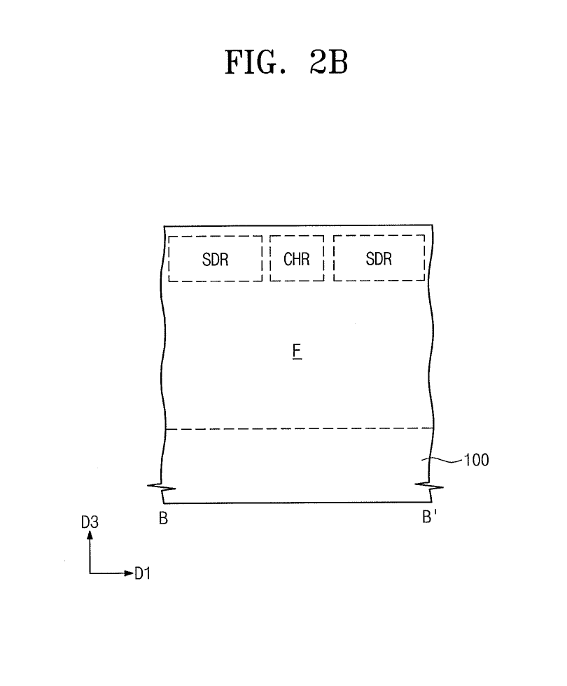

FIGS. 2A through 7A illustrate perspective views of a method of fabricating a semiconductor device according to other example embodiments. FIGS. 2B through 7B are sectional views taken along lines B-B′ of FIGS. 2A through 7A, respectively. For convenience in description, the aforesaid technical features may be omitted below.

Referring to FIGS. 2A and 2B, the fin portion F may be formed to protrude upward from the substrate 100. The fin portion F may extend along a direction D1. The substrate 100 may be a silicon wafer or a silicon on insulator (SOI) wafer. In example embodiments, the formation of the fin portion F may include forming a mask pattern (not shown) on the substrate 100 and etching the substrate 100 using the mask pattern as an etch mask to form a trench 101. In other example embodiments, the substrate 100 may be an SOI wafer including first and second semiconductor layers and a dielectric layer interposed therebetween, and the fin portion F may be formed by patterning the second semiconductor layer provided on the dielectric layer.

The device isolation pattern 110 may be formed to fill the trench 101. The device isolation pattern 110 may be formed of or include a high density plasma (HDP) oxide layer, a spin on glass (SOG) layer, and/or a chemical vapor deposition (CVD) oxide layer. The device isolation pattern 110 may be formed in the trench 101 to cover a lower side surface of the fin portion F. For example, an insulating layer may be formed to fill the trench 101, and then, an upper portion of the insulating layer may be etched to expose an upper portion of the fin portion F. In other example embodiments, the formation of the fin portion F may include forming a mask pattern on the top surface of the substrate 100 and performing an epitaxial process using the top surface of the substrate 100 exposed by the mask pattern as a seed layer. The fin portion F may be formed of the same material as the substrate 100 or a material having a lattice constant and/or band gap different from the substrate 100. For example, the substrate 100 may be formed of single crystalline silicon, and the fin portion F may include at least one of Ge, SiGe, or SiC. The fin portion F may include source/drain regions SDR and the channel region CHR interposed therebetween.

A doping process may be performed to adjust a threshold voltage of the fin portion F. In certain embodiments the semiconductor device 1 is an NMOS transistor, boron (B) may be used as dopants in the doping process. The semiconductor device 1 may be a PMOS transistor, and phosphorous (P) or arsenic (As) may be used as dopants in the doping process. In example embodiments, the doping process may be performed before or after the formation of the device isolation pattern 110.

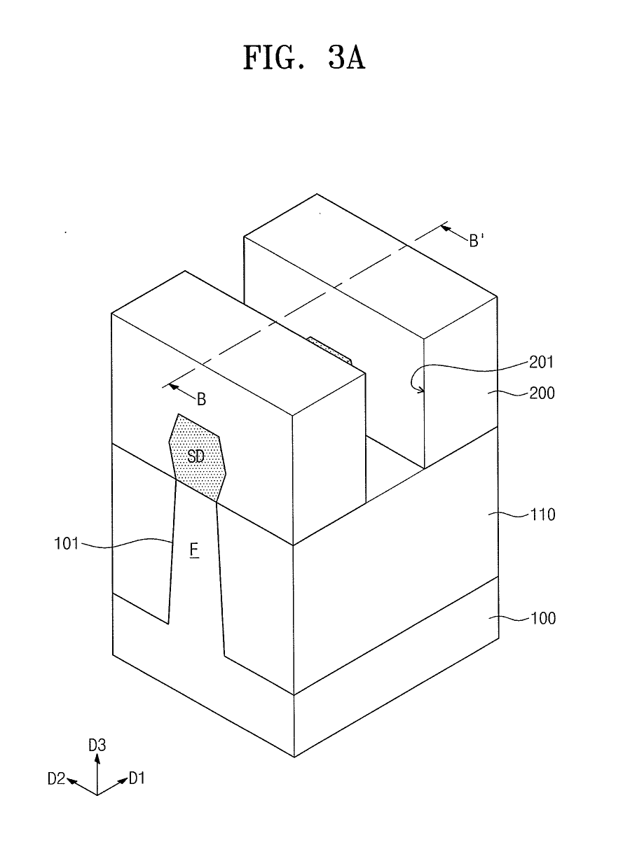

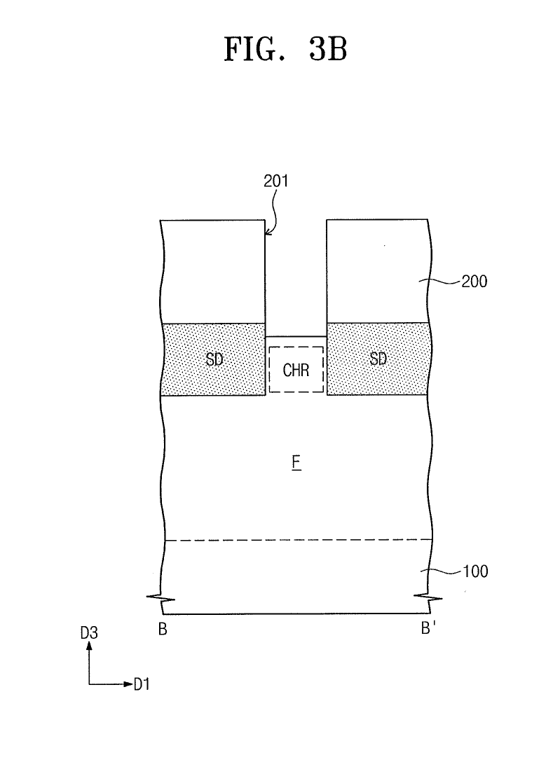

Referring to FIGS. 3A and 3B, the interlayered insulating layer 200 may be formed to have the opening 201. The opening 201 may be formed in the interlayered insulating layer 200 to cross the fin portion F. The opening 201 may be formed on the device isolation pattern 110 to extend parallel to the direction D2. The opening 201 may expose the top surface and both side surfaces of the channel region CHR of the fin portion F.

In example embodiments, a dummy gate pattern (not shown) may be formed on the substrate 100 to cross the fin portion F. The source/drain electrodes SD may be formed at both sides of the dummy gate pattern (not shown). The formation of the source/drain electrodes SD may include forming the source/drain regions SDR and forming an epitaxial layer. The source/drain electrodes SD may be formed of or include a SiGe-containing material. The source/drain electrodes SD may be formed at the source/drain regions SDR of the fin portion F, and the channel region CHR of the fin portion F may be interposed between the source/drain electrodes SD. The interlayered insulating layer 200 may be formed on the substrate 100 and the side surface of the dummy gate pattern, and a spacer (not shown) may be additionally formed on both of side surfaces of the dummy gate pattern. Thereafter, the dummy gate pattern may be removed to form the opening 201.

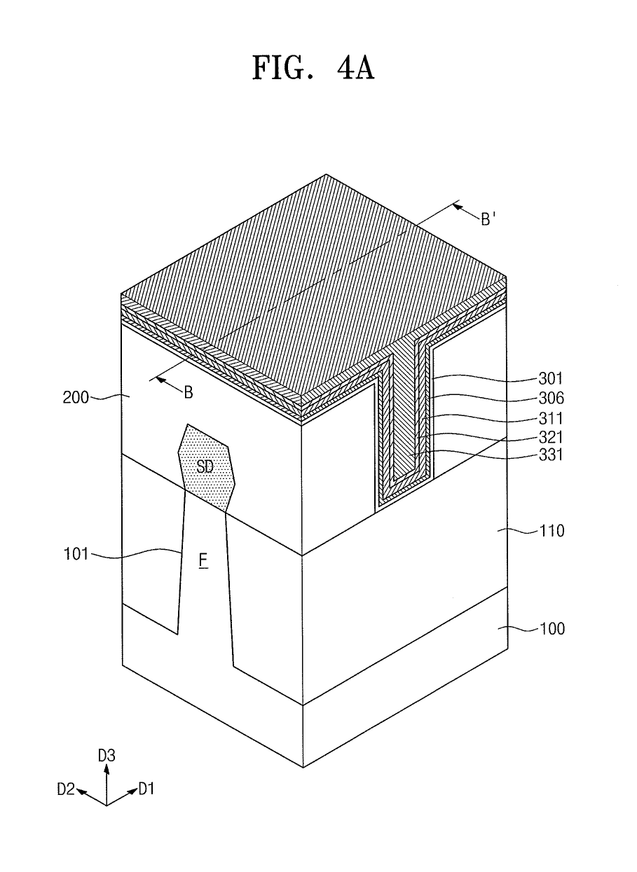

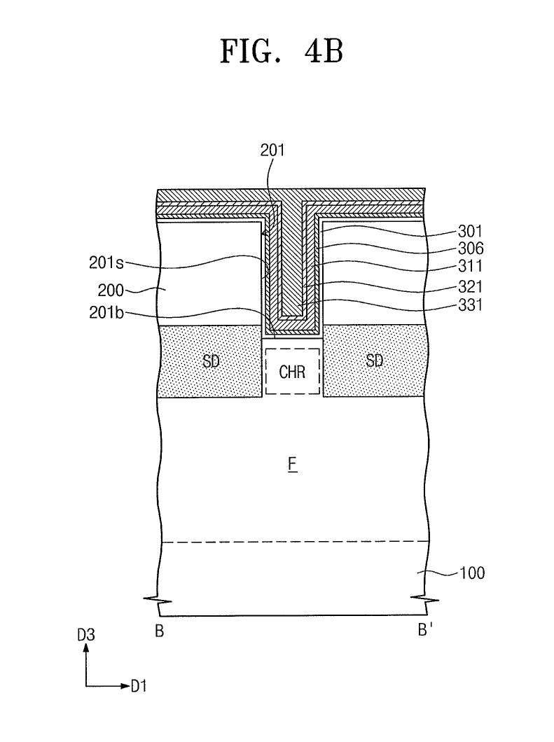

Referring to FIGS. 4A and 4B, a gate insulating layer 301, a first conductive layer 311, a barrier layer 321, and a second conductive layer 331 may be conformally formed on the substrate 100. For example, the gate insulating layer 301 may be formed on the bottom surface 201b and the side surface 201s of the opening 201 and a top surface of the interlayered insulating layer 200. The gate insulating layer 301 may be formed to cover all of side and top surfaces of the channel region CHR of the fin portion F. The gate insulating layer 301 may include at least one of hafnium-based materials (e.g., HfO₂, HfSiO, HfSiON, HfON, HfAlO, or HfLaO), silicate-based materials (e.g., AlSiO or TaSiO), zirconium-based materials (e.g., ZrO₂ or ZrSiO), lanthanide-based materials (e.g., La₂O₃, Pr₂O₃, or Dy₂O₃), and quaternary oxides (e.g., BST((Ba, Sr)TiO₃) or PZT (Pb(Zr, Ti)O₃)). In other example embodiments, before the formation of the gate insulating pattern 300, a dielectric layer (not shown) may be further formed. The dielectric layer (not shown) may be formed between the gate insulating layer 301 and the opening 201. The dielectric layer (not shown) may include at least one of silicon oxide, silicon nitride, silicon carbide, and silicon oxynitride.

An additional barrier layer 306 may be conformally formed on the gate insulating layer 301. The additional barrier layer 306 may include at least one of TiN, TaN, WN, HfN, TiAlN, TaAlN, or HfAlN. In other example embodiments, the formation of the additional barrier layer 306 may be omitted.

The first conductive layer 311 may be conformally formed on the additional barrier layer 306. For example, the first conductive layer 311 may be formed on the top surface of the interlayered insulating layer 200 and the side surface 201s and the bottom surface 201b of the opening 201. The first conductive layer 311 may include one of Ti, Ta, Hf, Mo, Al, alloys thereof, nitrides thereof, and carbides thereof. In other example embodiments, the first conductive pattern 310 may include at least one of Pt, Ru, IrO, or RuO.

The barrier layer 321 may be formed on the first conductive layer 311. For example, after the formation of the first conductive layer 311, the barrier layer 321 may be formed on the top surface of the interlayered insulating layer 200, the side surface 201s and the bottom surface 201b of the opening 201. The barrier layer 321 may include at least one of TiN, TaN, WN, MN, TiAlN, TaAlN, or HfAlN.

The second conductive layer 331 may be formed on the barrier layer 321. For example, the second conductive layer 331 may be formed by an atomic layer deposition (ALD) or chemical vapor deposition (CVD) process. The second conductive layer 331 may be formed to fill the opening 201. Further, the second conductive layer 331 may be formed to include a portion disposed on the top surface of the interlayered insulating layer 200. The second conductive layer 331 may include a metallic material (e.g., tungsten). A residue may be produced in the process of forming the second conductive layer 331, and the second conductive layer 331 may contain such a residue. For example, a residue, such as fluorine, carbon, or oxygen, may be contained in the second conductive layer 331.

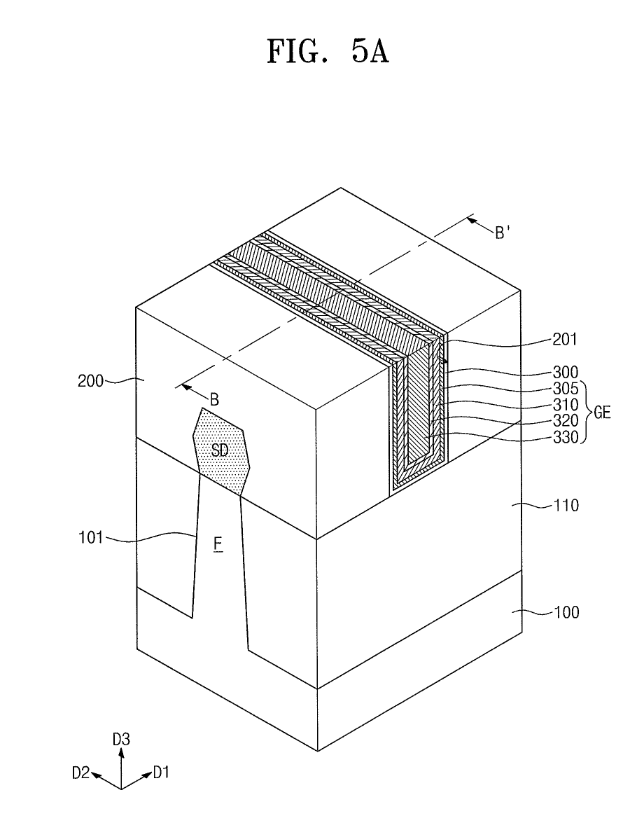

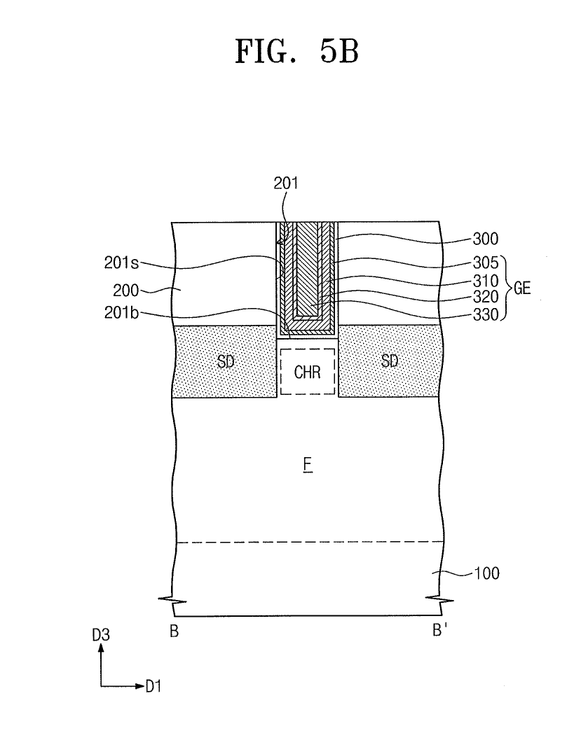

Referring to FIGS. 5A and 5B, the gate insulating pattern 300, the additional barrier pattern 305, the first conductive pattern 310, the barrier pattern 320, and the second conductive pattern 330 may be formed in the opening 201. For example, this process may include planarizing the gate insulating layer 301, the additional barrier layer 306, the first conductive layer 311, the barrier layer 321, and the second conductive layer 331. The additional barrier layer 306, the first conductive layer 311, the barrier layer 321, and the second conductive layer 331 may be removed from the top surface of the interlayered insulating layer 200, the interlayered insulating layer 200 may be exposed, and the gate insulating pattern 300 and the gate electrode GE may be formed in the opening 201. The gate electrode GE may include the first conductive pattern 310, the barrier pattern 320, and the second conductive pattern 330. In certain embodiments, the gate electrode GE may further include the additional barrier pattern 305. The planarization of the interlayered insulating layer 200 may be performed using an etch-back process or a chemical mechanical polishing (CMP) process.

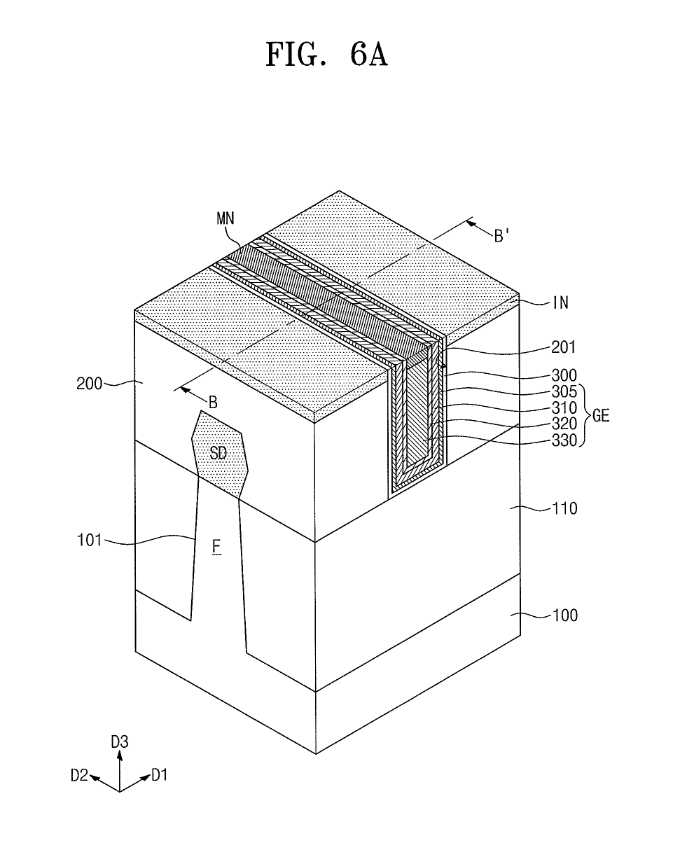

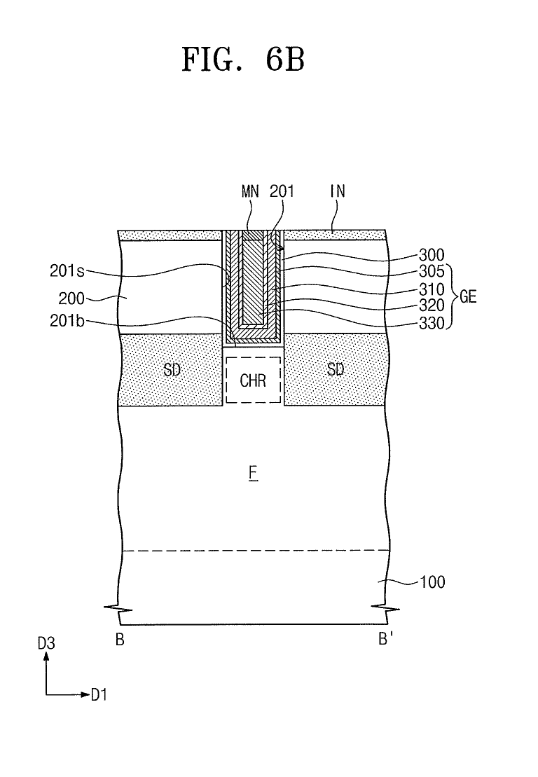

Referring to FIGS. 6A and 6B, an upper portion of the second conductive pattern 330 may be nitrified to form the metal nitride layer MN, and the metal nitride layer MN may be formed on the second conductive pattern 330. For example, the formation of the metal nitride layer MN may include performing a plasma nitrification process or a thermal nitrification process on the gate electrode GE and the interlayered insulating layer 200. The nitrification process may be performed using a nitrogen-containing gas (e.g., ammonia (NH₃) and/or nitrogen (N₂)). The nitrification process may be performed at a temperature ranging from 300° C. to 500° C. If the nitrification process is performed at a temperature lower than 300° C. lower, the upper portion of the second conductive pattern 330 may not be nitrified. If the nitrification process is performed at a temperature higher than 500° C., the semiconductor device 1 may be damaged.

The metal nitride layer MN is formed by nitriding the upper portion of the second conductive pattern 330, and the metal nitride layer MN may contain the same metallic element as the second conductive pattern 330. For example, the second conductive pattern 330 may contain tungsten, and the metal nitride layer MN may include tungsten nitride. The metal nitride layer MN may include a metallic element different from a metallic element contained in the first conductive pattern 310. Upper portions of the additional barrier pattern 305, the barrier pattern 320, the first conductive pattern 310, and the gate insulating pattern 300 may not be nitrified during the nitrification process for forming the metal nitride layer MN, and the metal nitride layer MN may not extend onto the barrier pattern 320 and the first conductive pattern 310. The metal nitride layer MN may be spaced apart from the first conductive pattern 310. The metal nitride layer MN may be formed to have a thickness ranging from about 1 nm to 10 nm.

In the nitrification process, an upper portion of the interlayered insulating layer 200 may be nitrified to form the insulating nitride layer IN. In example embodiments, the insulating nitride layer IN may be formed of or include at least one of silicon nitride, silicon oxynitride, or silicon carbonitride. The insulating nitride layer IN may be simultaneously formed with the metal nitride layer MN. The insulating nitride layer IN may be formed spaced apart from the metal nitride layer MN and the first conductive pattern 310.

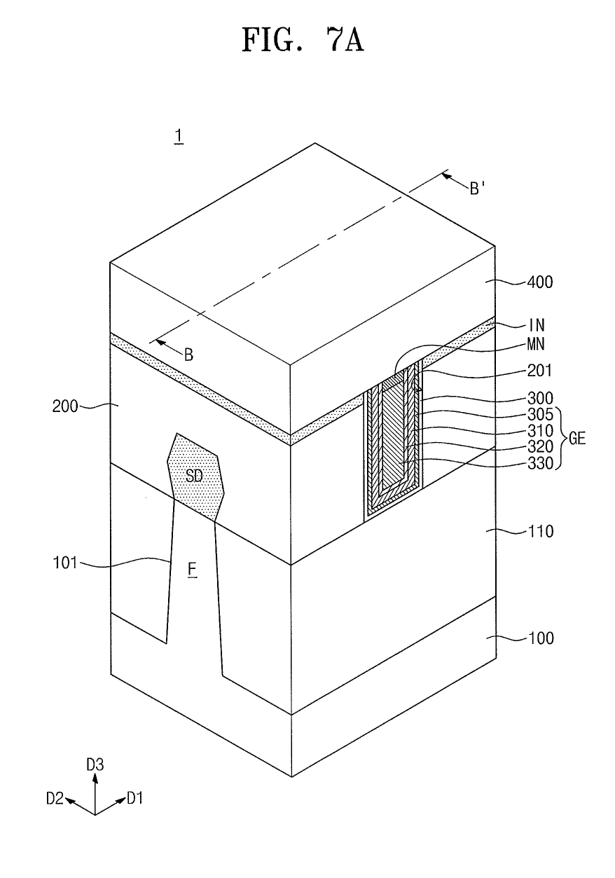

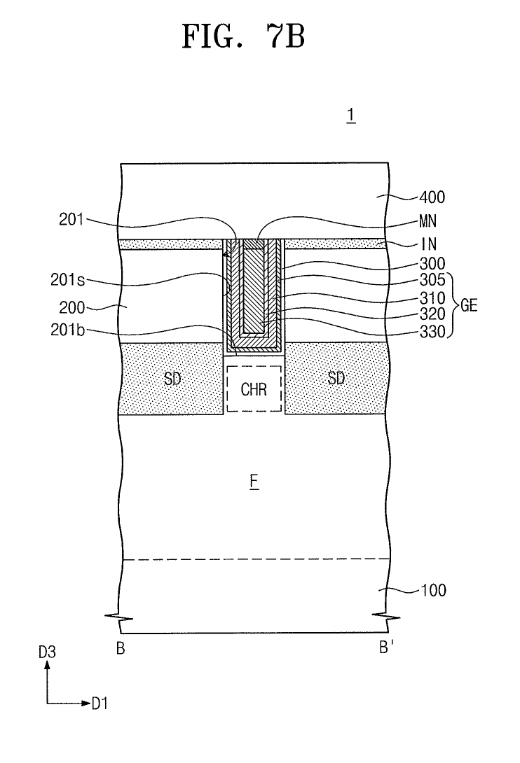

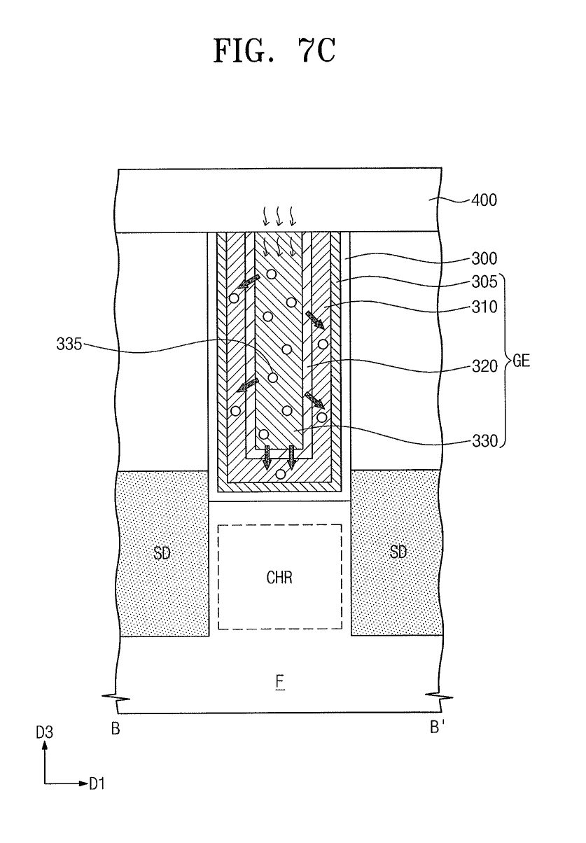

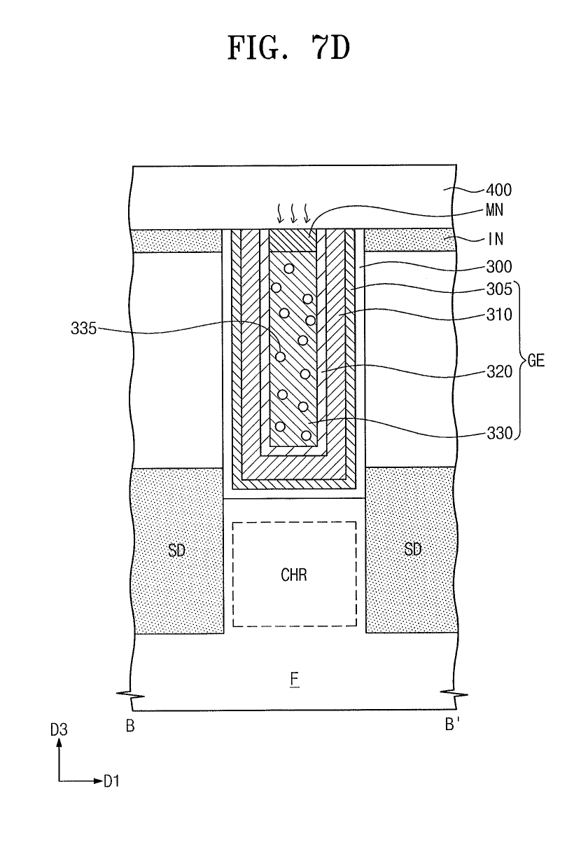

Referring to FIGS. 7A and 7B, the oxide layer 400 may be formed on the gate insulating layer 301. The oxide layer 400 may be formed using, for example, a deposition process. As an example, the oxide layer 400 may include silicon oxide.

A role of the metal nitride layer in a process of forming the oxide layer will be described below.

FIG. 7C illustrates a process of forming an oxide layer in the absence of the metal nitride layer, and FIG. 7D illustrates a process of forming an oxide layer in the presence of the metal nitride layer.

As shown in FIG. 7C, the oxide layer 400 may be in contact with the second conductive pattern 330. When the metal nitride layer MN is not provided, the upper portion of the second conductive pattern 330 may be oxidized in the process of forming the oxide layer 400. Further, heat to be produced in the process of forming the oxide layer 400 may be applied to the second conductive pattern 330 or oxygen atoms contained in the oxide layer 400 may be infiltrated into the second conductive pattern 330, and residues 335 contained in the second conductive pattern 330 may be infiltrated into the first conductive pattern 310 through the barrier layer 321. The residues 335 may contain fluorine, carbon, or oxygen. The presence of the infiltrated residues 335 may lead to a change in the work function of the first conductive pattern 310, and it may become difficult to adjust the threshold voltage of the channel region CHR. As an example, when the residues 335 are infiltrated into the first conductive pattern 310, the first conductive pattern 310 may have a work function of 5.1 eV of higher.

By contrast, as shown in FIG. 7D, the metal nitride layer MN may be interposed between the second conductive pattern 330 and the oxide layer 400. The metal nitride layer MN may serve as a barrier layer for preventing oxygen atoms from being diffused from the oxide layer 400 to the second conductive pattern 330, and the upper portion of the second conductive pattern 330 may be prevented from being oxidized by the oxide layer 400. Further, the metal nitride layer MN may prevent heat energy, which may be generated in a deposition process of the oxide layer 400, from being transmitted into the second conductive pattern 330, and the residues 335, which may be contained in the second conductive pattern 330, may be prevented from being diffused into the first conductive pattern 310. For example, the second conductive pattern 330 may contain fluorine, and the first conductive pattern 310 may not contain fluorine. The first conductive pattern 310 may not contain the residues 335, and the work function of the first conductive pattern 310 and the threshold voltage of the channel region CHR may be controlled. In example embodiments, the first conductive pattern 310 may have a work function ranging from 4.1 eV to 5.1 eV, after the formation of the oxide layer 400.

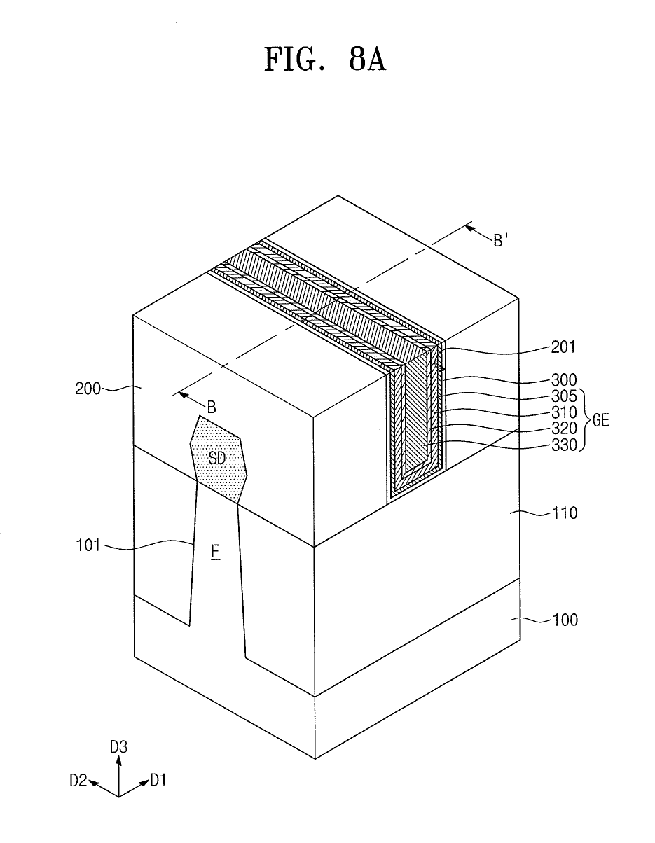

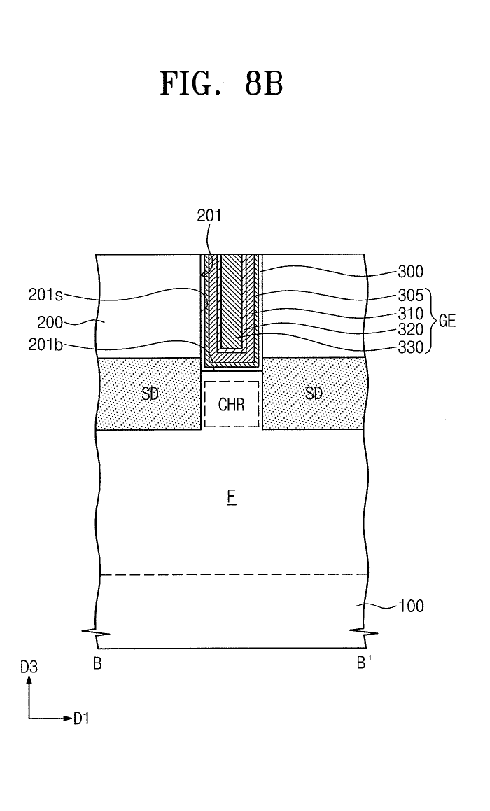

FIGS. 8A through 10A illustrate perspective views of a method of fabricating a semiconductor device according to still other example embodiments, and FIGS. 8B through 10B are sectional views taken along lines B-B′ of FIGS. FIGS. 8A through 10A, respectively. For convenience in description, the aforesaid technical features may be omitted below.

Referring to FIGS. 8A and 8B, the fin portion F may protrude upward from the substrate 100. The interlayered insulating layer 200 may be provided on the substrate 100 to have the opening 201. As shown in FIGS. 5A and 5B, the gate insulating pattern 300, the first conductive pattern 310, the additional barrier pattern 305, the barrier pattern 320, and the second conductive pattern 330 may be formed in the opening 201. The first conductive pattern 310 may be a metal layer for adjusting a work function of the gate electrode GE. In certain embodiments, the additional barrier pattern 305 may be omitted.

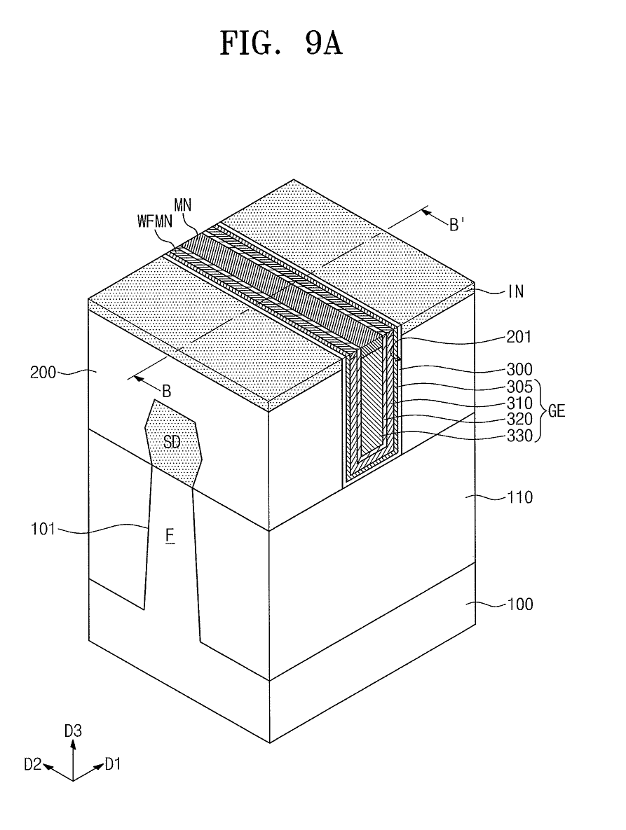

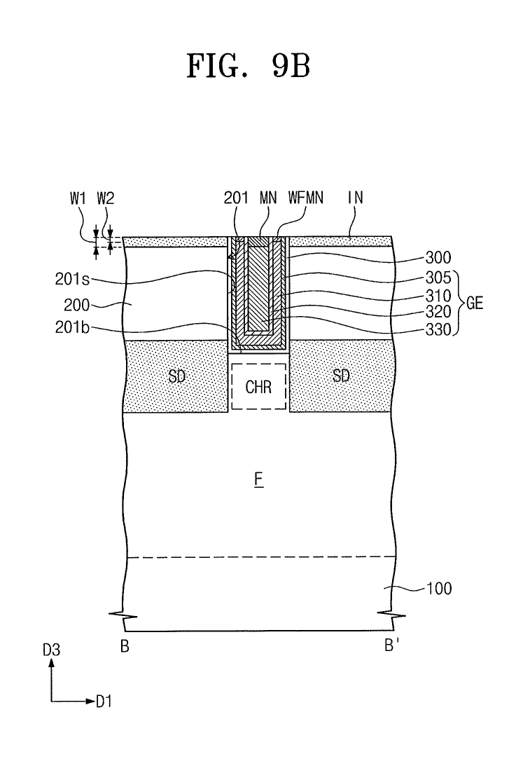

Referring to FIGS. 9A and 9B, the metal nitride layer MN, a work-function metal nitride layer WFMN, and the insulating nitride layer IN may be formed using the same nitrification process. For example, the formation of the metal nitride layer MN, the work-function metal nitride layer WFMN, and the insulating nitride layer IN may include performing a plasma nitrification process or a thermal nitrification process on the gate electrode GE and the interlayered insulating layer 200. The nitrification process may be performed using a nitrogen-containing gas (e.g., ammonia (NH₃) and/or nitrogen (N₂)) at a temperature ranging from 300° C. to 500° C.

The upper portion of the second conductive pattern 330 may be nitrified to form the metal nitride layer MN. The metal nitride layer MN may contain the same metallic element as one contained in the second conductive pattern 330. For example, the second conductive pattern 330 may include tungsten, and the metal nitride layer MN may include tungsten nitride. The metal nitride layer MN may be formed not to cover the barrier pattern 320. The metal nitride layer MN may be spaced apart from the first conductive pattern 310 and may include a different metallic element from one contained in the first conductive pattern 310.

An upper portion of the first conductive pattern 310 may be nitrified to form the work-function metal nitride layer WFMN. The work-function metal nitride layer WFMN may contain the same metallic element as the first conductive pattern 310 but may contain a different material as the second conductive pattern 330. In example embodiments, the work-function metal nitride layer WFMN may be formed of or include, for example, at least one of nitrides of Ti, Ta, Hf, Mo, alloys thereof, and carbides thereof. It is more difficult to nitrify the first conductive pattern 310, compared with the second conductive pattern 330, and the work-function metal nitride layer WFMN may be formed to have a thickness W2 that is smaller than a thickness W1 of the metal nitride layer MN. For example, the thickness W2 of the work-function metal nitride layer WFMN may range from about 0.01 nm to 2 nm, and the thickness W1 of the metal nitride layer MN may range from about 1 nm to 10 nm. The work-function metal nitride layer WFMN may not extend onto the barrier pattern 320. The barrier pattern 320 may be interposed between side surfaces of the metal nitride layer MN and the work-function metal nitride layer WFMN. The work-function metal nitride layer WFMN may be formed spaced apart from the metal nitride layer MN and the insulating nitride layer IN. The work-function metal nitride layer WFMN may contain a different material from the metal nitride layer MN. In certain embodiments, upper portions of the additional barrier pattern 305, the barrier pattern 320, and the gate insulating pattern 300 may not be nitrified during the nitrification process for forming the metal nitride layer MN and the work-function metal nitride layer WFMN.

An upper portion of the interlayered insulating layer 200 may be nitrified to form the insulating nitride layer IN. In example embodiments, the insulating nitride layer IN may be formed of or include at least one of silicon nitride, silicon oxynitride, or silicon carbonitride. The insulating nitride layer IN may be spaced apart from the metal nitride layer MN. The gate insulating pattern 300 may be interposed between the work-function metal nitride layer WFMN and the insulating nitride layer IN. The insulating nitride layer IN may include a different material from the metal nitride layer MN and the work-function metal nitride layer WFMN.

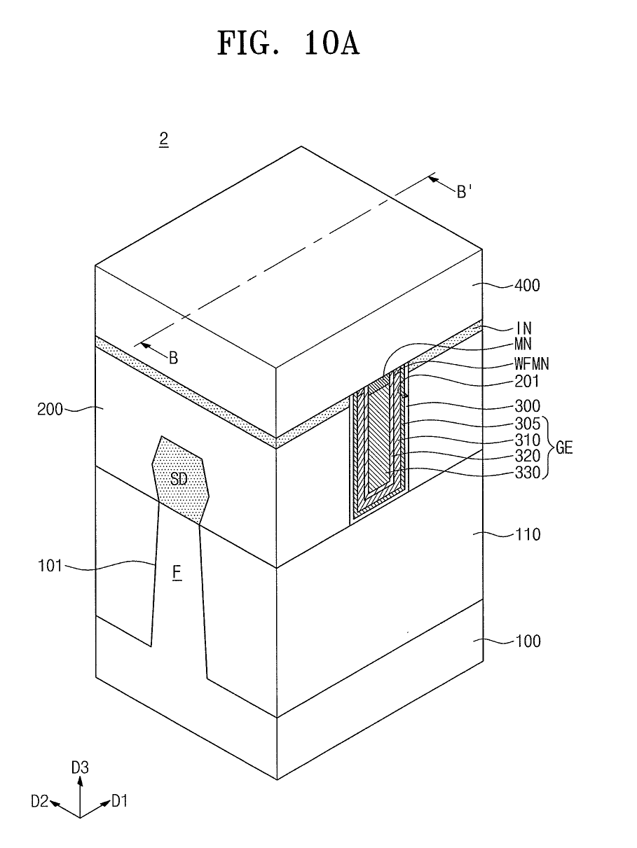

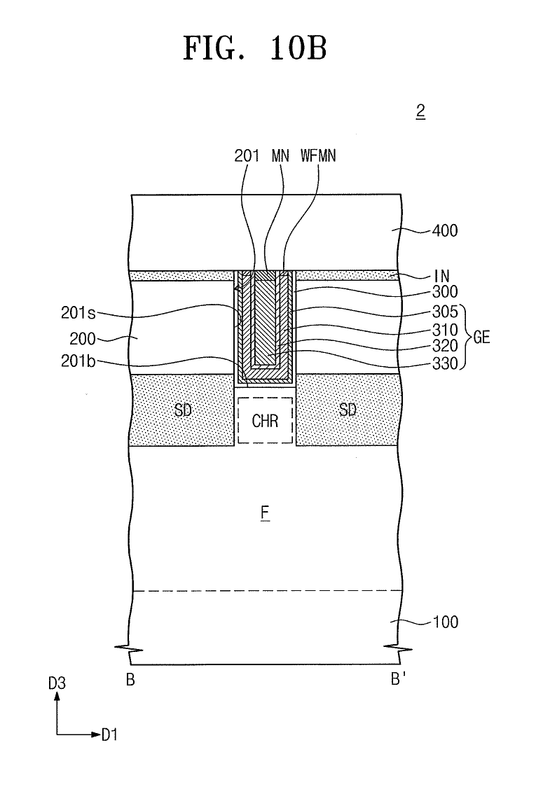

Referring to FIGS. 10A and 10B, the oxide layer 400 may be formed on the gate electrode GE. The oxide layer 400 may be formed using, for example, a deposition process. The metal nitride layer MN may be interposed between the second conductive pattern 330 and the oxide layer 400. The metal nitride layer MN may serve as a barrier layer for preventing oxygen atoms from being diffused from the oxide layer 400 to the second conductive pattern 330. Further, the metal nitride layer MN may prevent heat energy, which may be generated in a deposition process of the oxide layer 400, from being transmitted into the second conductive pattern 330. After the formation of the metal oxide layer 400, the first conductive pattern 310 may have a work function ranging from 4.1 eV to 5.1 eV. The work function of the first conductive pattern 310 may be adjusted to control the threshold voltage of the channel region CHR. The fabrication of the semiconductor device 2, according to other example embodiments, may be finished.

In an example embodiment, the semiconductor device 1 or 2 may be a CMOS device, and the formation of the gate electrode may include forming a gate electrode for an NMOS FET.

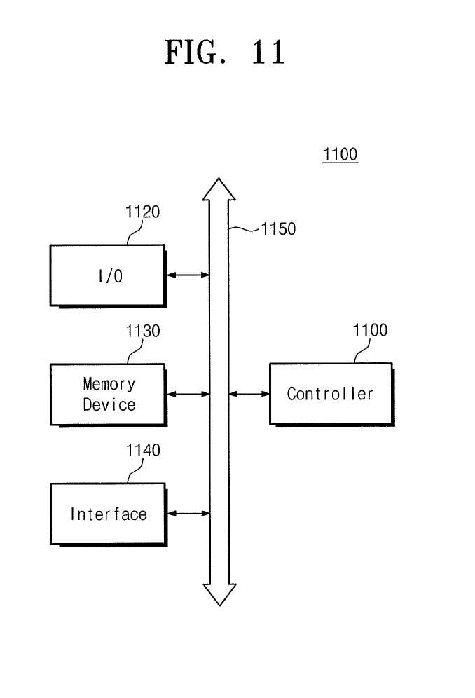

FIG. 11 illustrates a schematic block diagram of an example of electronic systems including a semiconductor device according to example embodiments.

Referring to FIG. 11, an electronic system 1100 according to example embodiments may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other via the data bus 1150. The data bus 1150 may correspond to a path through which electrical signals are transmitted.

The controller 1110 may include at least one of a microprocessor, a digital signal processor, a microcontroller or another logic device. The other logic device may have a similar function to any one of the microprocessor, the digital signal processor and the microcontroller. The controller 1110 may include at least one of the afore-described semiconductor devices. The I/O unit 1120 may include a keypad, a keyboard or a display unit. The memory device 1130 may store data and/or commands. In example embodiments, the memory device 1130 may include one of nonvolatile memory devices, such as FLASH, magnetic, and/or phase-changeable memory devices. For example, the memory device 1130 may be a nonvolatile memory device including at least one of the afore-described semiconductor devices. The interface unit 1140 may transmit electrical data to a communication network or may receive electrical data from a communication network. The interface unit 1140 may operate by wireless or cable. For example, the interface unit 1140 may include an antenna for wireless communication or a transceiver for cable communication. The electronic system 1100 may further include a fast DRAM device and/or a fast SRAM device that acts as a cache memory for improving an operation of the controller 1110. The cache memory may be configured to include at least one of the afore-described semiconductor devices.

The electronic system 1100 may be applied to a personal digital assistant (PDA), a portable computer, a web tablet, a wireless phone, a mobile phone, a digital music player, a memory card or an electronic product. The electronic product may receive or transmit information data wirelessly.

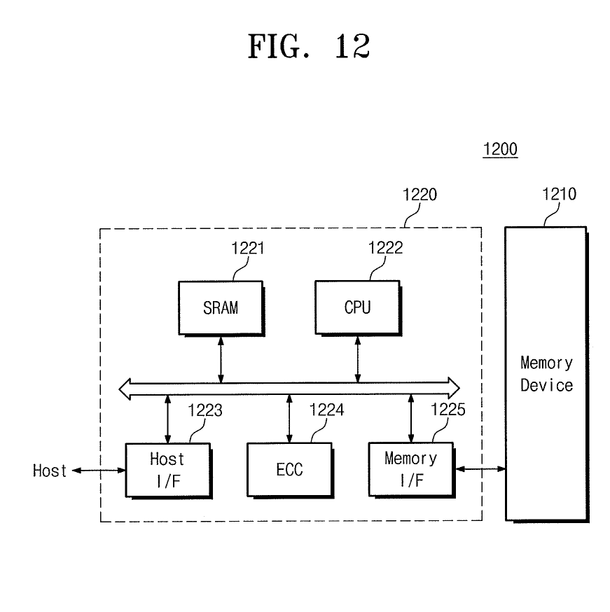

FIG. 12 illustrates a schematic block diagram of an example of memory systems including a semiconductor device according to the embodiments.

Referring to FIG. 12, a memory system 1200 according to example embodiments may include a memory device 1210. The memory device 1210 may be, for example, one of nonvolatile memory devices, such as FLASH, magnetic, and/or phase-changeable memory devices, including at least one of the afore-described semiconductor devices. The memory system 1200 may include a memory controller 1220 that controls data communication between a host and the memory device 1210.

The memory controller 1220 may include a processing unit 1222 that controls overall operations of the memory system 1200. The processing unit 1222 may be or include at least one of the afore-described semiconductor devices. In addition, the memory controller 1220 may include an SRAM device 1221 used as an operation memory of the processing unit 1222. The SRAM device 1221 may include or be at least one of the afore-described semiconductor devices. Moreover, the memory controller 1220 may further include a host interface unit 1223 and a memory interface unit 1225. The host interface unit 1223 may be configured to include a data communication protocol between the memory system 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. The memory system 1200 may further include a read only memory (ROM) device that stores code data to interface with the host. The memory system 1200 may be used as a portable data storage card. Alternatively, the memory system 1200 may be provided in the form of solid state disks (SSD), instead of hard disks of computer systems.

According to example embodiments, an upper portion of a second conductive pattern of a gate electrode may be nitrified to form a metal nitride layer. The metal nitride layer may contain the same material as the second conductive pattern. An oxide layer may be formed on the gate electrode. The metal nitride layer may be interposed between the second conductive pattern and the oxide layer. The metal nitride layer may serve as a barrier for preventing oxygen atoms in the oxide layer and heat from being infiltrated into the second conductive pattern during or after the formation of the oxide layer, and the semiconductor device may have a reduced threshold voltage property.

Example embodiments may provide a semiconductor device including a field effect transistor, for example, a fin field effect transistor (FinFET), with improved threshold voltage property, and a method of fabricating the same.

Other example embodiments may provide a semiconductor device including a highly reliable field effect transistor and a method of fabricating the same.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of fabricating a semiconductor device, the method comprising:
forming, on a substrate, an interlayered insulating layer having an opening;
sequentially forming a first conductive pattern, a barrier pattern, and a second conductive pattern on bottom and side surfaces of the opening; and
nitrifying an upper portion of the second conductive pattern to form a metal nitride layer spaced apart from the first conductive pattern.

2. The method as claimed in claim 1, wherein the metal nitride layer contains a different metallic element from one contained in the first conductive pattern.

3. The method as claimed in claim 1, wherein forming the first conductive pattern, the barrier pattern, and the second conductive pattern includes:
conformally forming a first conductive layer on a top surface of the interlayered insulating layer and on the bottom and side surfaces of the opening;
conformally forming a barrier layer on the first conductive layer; and
forming a second conductive layer on the barrier layer to fill the opening.

4. The method as claimed in claim 3, wherein forming the first conductive pattern, the barrier pattern, and the second conductive pattern further includes planarizing the first conductive layer, the barrier layer, and the second conductive layer to expose the interlayered insulating layer.

5. The method as claimed in claim 1, wherein:
nitrifying the upper portion of the second conductive pattern includes nitrifying an upper portion of the first conductive pattern to form a work-function metal nitride layer, and
the work-function metal nitride layer contains a different material from the metal nitride layer.

6. The method as claimed in claim 5, wherein the work-function metal nitride layer is spaced apart from the metal nitride layer.

7. The method as claimed in claim 1, further comprising forming a gate insulating layer between the first conductive pattern and the opening.

8. The method as claimed in claim 1, further comprising forming an oxide layer on the metal nitride layer, wherein the first conductive pattern has a work function ranging from 4.1 eV to 5.1 eV, after the oxide layer is formed.

9. The method as claimed in claim 1, wherein nitrifying the upper portion of the second conductive pattern includes nitrifying an upper portion of the interlayered insulating layer to form an insulating nitride layer.

10. A semiconductor device, comprising:
a substrate;
an interlayered insulating layer on the substrate and having an opening; and
a gate electrode in the opening, the gate electrode including:
a first conductive pattern on bottom and side surfaces of the opening;
a second conductive pattern on the first conductive pattern;
a metal nitride layer spaced apart from the first conductive pattern, on the second conductive pattern; and
a barrier layer between the first and second conductive patterns.

11. The device as claimed in claim 10, wherein:
the second conductive contains a different material from the first conductive pattern; and
the metal nitride layer contains a same metal material as the second conductive pattern.

12. The device as claimed in claim 11, wherein the metal nitride layer contains a different metallic element from one contained in the first conductive pattern.

13. The device as claimed in claim 11, further comprising a work-function metal nitride layer on the first conductive pattern and spaced apart from the metal nitride layer.

14. The device as claimed in claim 13, wherein the work-function metal nitride layer is thinner than the metal nitride layer.

15. The device as claimed in claim 11, wherein the first conductive pattern has a work function ranging from 4.1 eV to 5.1 eV.

16. The device as claimed in claim 11, further comprising a gate insulating layer between the opening and the first conductive pattern.

17. A method of preventing impurities from infiltrating into a first conductive pattern from a second conductive pattern, the method comprising:
forming the first conductive pattern and the second conductive pattern;
nitrifying a portion of the second conductive pattern to form a metal nitride layer; and
depositing an oxide layer on the metal nitride layer.

18. The method as claimed in claim 17, wherein the metal nitride layer is interposed between the oxide layer and a portion of the second conductive pattern that is not nitrified.

19. The method of claim 17, wherein depositing the oxide layer on the metal nitride layer includes depositing the oxide layer on an exposed portion of the first conductive pattern.

20. The method of claim 17, wherein the metal nitride layer prevents a portion of the second conductive pattern that is not nitrified from being oxidized during depositing of the oxide layer.
